(19) United States
(12) Patent Application Publication
(10) Pub. No.: US 2025/0046635 A1
(43) Pub. Date: Feb. 6, 2025

(54) SUBSTRATE PROCESSING

(71) Applicant: SAMSUNG ELECTRONICS CO., LTD., Suwon-si (KR)

(72) Inventors: Sangchul Han, Suwon-si (KR); Yihwan Kim, Suwon-si (KR); Youngbok Lee, Suwon-si (KR); Junho Lee, Suwon-si (KR); SeokJun Hong, Suwon-si (KR)

(21) Appl. No.: 18/666,563

(22) Filed: May 16, 2024

(30) Foreign Application Priority Data
Aug. 3, 2023 (KR) 10-2023-0101404

(51) Int. Cl. H01L 21/67; H01J 37/32; H01L 21/687

(52) U.S. Cl. CPC H01L 21/67259; H01J 37/321; H01J 37/32155; H01J 37/3244; H01J 37/32697; H01J 37/32724; H01J 37/32944; H01L 21/68757; H01J 2237/3321; H01J 2237/334

(57) ABSTRACT

A method of processing a substrate includes locating a substrate in a substrate processing apparatus, fixing the substrate in the substrate processing apparatus, processing the substrate, and checking a fixed state of the substrate. The substrate processing apparatus includes a process chamber, a stage supporting the substrate, a plasma induction electrode used to generate plasma and located in the stage, a first power source configured to supply RF power to the plasma induction electrode, a heater located in the stage and used to heat the stage, a second power source configured to supply AC power to the heater, and a monitoring unit electrically connected to the plasma induction electrode. The checking of the fixed state of the substrate includes measuring AC-2 power of the AC power, which is transferred to the monitoring unit through the heater and the plasma induction electrode.

### CROSS-REFERENCE TO RELATED APPLICATION

This U.S. non-provisional patent application claims priority under 35 U.S.C. § 119 to Korean Patent Application No. 10-2023-0101404, filed on Aug. 3, 2023, in the Korean Intellectual Property Office, the entire contents of which are hereby incorporated by reference.

### BACKGROUND

Semiconductor processes may include various processes (e.g., photolithography, etching, deposition, etc.). A substrate may be used to manufacture a semiconductor device. Here, the substrate should be fixed on a stage in a process chamber to perform the semiconductor process as desired by an operator.

### SUMMARY

The present disclosure relates to substrate processing methods. In general, in some aspects, the subject matter of the present disclosure encompasses methods of processing a substrate, in which the methods include checking a fixed state of a substrate by measuring a heater voltage at a plasma induction electrode.

Implementations of the methods disclosed herein may include one or more of the following features. For example, in some implementations of the methods include checking a fixed state of a substrate regardless of a type of a plasma induction electrode.

In some implementations, of the methods include checking a fixed state of a substrate without measuring a change in gas leak.

In some implementations, the methods include checking a fixed state of a substrate at a high process temperature.

In some implementations, the methods include measuring a change in heater voltage at a plasma induction electrode according to a change in resistance according to a change in contact state between a substrate and a stage.

In general, in some aspects, the subject matter of the present disclosure is directed to methods of processing a substrate that include: locating a substrate in a substrate processing apparatus; fixing the substrate in the substrate processing apparatus; processing the substrate; and checking a fixed state of the substrate. The substrate processing apparatus may include a process chamber providing a process space, a stage supporting the substrate, a plasma induction electrode used to generate plasma and located in the stage, a first power source configured to supply RF power to the plasma induction electrode, a heater located in the stage and used to heat the stage, a second power source configured to supply AC power to the heater, and a monitoring unit electrically connected to the plasma induction electrode. The processing of the substrate may include heating the stage by supplying the AC power to the heater by the second power source. The checking of the fixed state of the substrate may include measuring AC-2 power of the AC power, which is transferred to the monitoring unit through the heater and the plasma induction electrode.

In general, in some aspects, the subject matter of the present disclosure is directed to methods of processing a substrate that include: locating a substrate in a substrate processing apparatus; fixing the substrate in the substrate processing apparatus; processing the substrate; and checking a fixed state of the substrate. The substrate processing apparatus may include a process chamber providing a process space, a stage supporting the substrate, a plasma induction electrode used to generate plasma, a first power source comprising a RF power source configured to supply RF power to the plasma induction electrode and an alternating current filter configured to filter the RF power, a heater located in the stage and used to heat the stage, a second power source configured to supply AC power to the heater, and a monitoring unit configured to measure a change in AC-2 power supplied from the second power source and passed through the heater, the plasma induction electrode and the alternating current filter. The checking of the fixed state of the substrate may include measuring the AC-2 power.

In general, in some aspects, the subject matter of the present disclosure is directed to methods of processing a substrate that include: fixing a substrate in a substrate processing apparatus; processing the substrate; checking a fixed state of the substrate; and checking an arcing state of the substrate. The substrate processing apparatus may include a process chamber providing a process space, a stage supporting the substrate, a plasma induction electrode located in the stage and used to generate plasma, a first power source comprising a RF power source electrically connected to the plasma induction electrode and configured to supply RF power, a heater located in the stage and used to heat the stage, a second power source comprising an AC power source configured to supply AC power to the heater, and a monitoring unit connected to the first power source and configured to analyze a state of a substrate. The processing of the substrate may include heating the stage by supplying the AC power to the heater by the AC power source. The checking of the fixed state of the substrate may include measuring AC-2 power transferred from the AC power source to the monitoring unit through the heater and the plasma induction electrode. The checking of the arcing state of the substrate may include measuring RF-2 power supplied from the RF power source and transferred to the monitoring unit through the substrate and the plasma induction electrode.

### BRIEF DESCRIPTION OF THE DRAWINGS

FIG. 1 is a cross-sectional view illustrating a substrate processing apparatus according to some implementations.

FIG. 2 is an enlarged view illustrating a portion of a substrate processing apparatus according to some implementations.

FIG. 3 is an enlarged view illustrating a portion of a substrate processing apparatus according to some implementations.

FIG. 4 is a schematic closed-circuit diagram illustrating a portion of a substrate processing apparatus according to some implementations.

FIG. 5 is a schematic view illustrating a first power source and a monitoring unit according to some implementations.

FIG. 6 is a schematic view illustrating a first power source and a monitoring unit according to some implementations.

FIG. 7 is a graph showing a change in heater voltage at a plasma induction electrode according to a change in distance between a substrate and a stage.

FIG. 8 is a flow chart illustrating a method of processing a substrate according to some implementations.

FIG. 9 is a cross-sectional view illustrating a substrate processing apparatus according to some implementations.

### DETAILED DESCRIPTION

Hereinafter, implementations will be described in detail with reference to the accompanying drawings. The same reference numerals or the same reference designators may denote the same components or elements throughout the specification.

In semiconductor processing, if the substrate is not fixed on the stage, heat may not be uniformly transferred to the substrate, and thus a process (e.g., deposition or etching) may not be uniformly performed on the substrate. A state of fixation of the substrate (sometimes referred to as a fixed state of the substrate) may be changed by various factors such as a temperature and/or a pressure in the process chamber. Aspects of this disclosure provide processes and systems for measuring the state of fixation.

Hereinafter, a reference designator D1 may be referred to as a first direction, a reference designator D2 intersecting the first direction D1 and perpendicular to the first direction D1 may be referred to as a second direction, and a reference designator D3 intersecting both the first direction D1 and the second direction D2, and perpendicular to both the first direction D1 and the second direction D2, may be referred to as a third direction. The first direction D1 may be referred to as an upward direction, and a direction opposite to the first direction D1 may be referred to as a downward direction. In addition, each of the second direction D2 and the third direction D3 may be referred to as a horizontal direction.

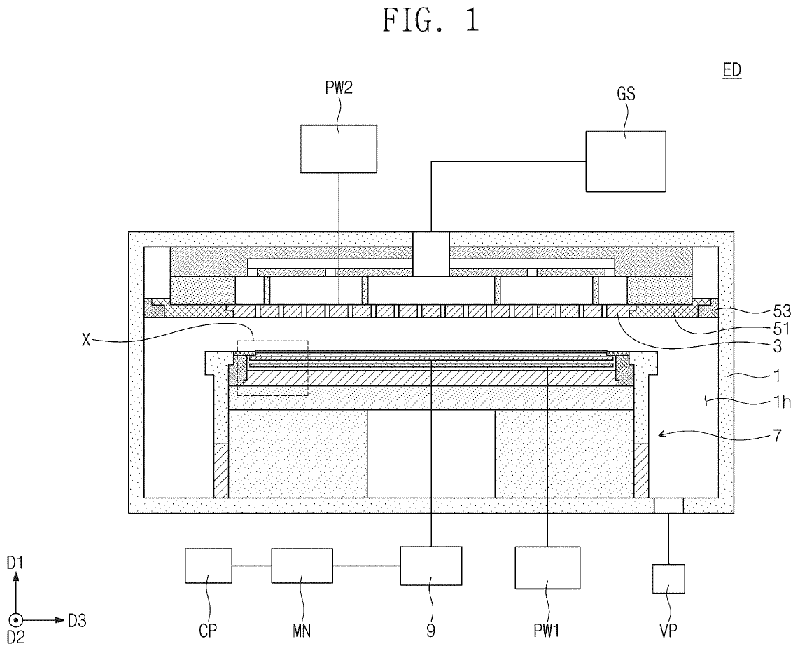

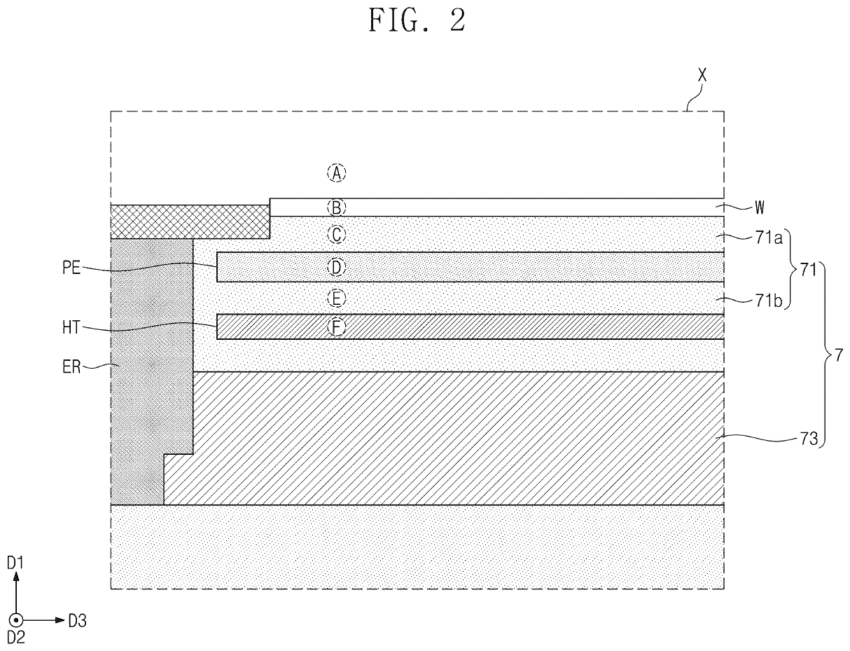

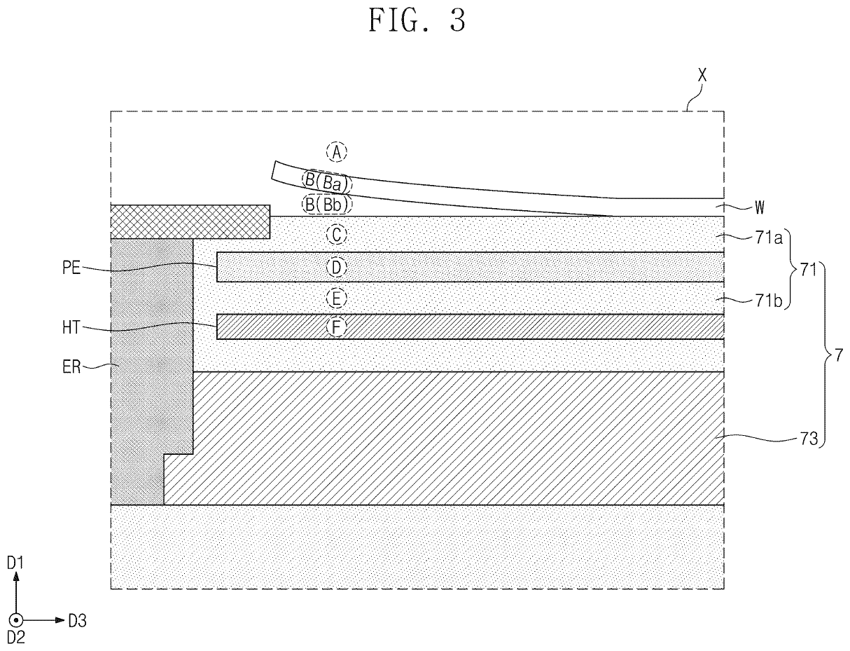

FIG. 1 is a cross-sectional view illustrating a substrate processing apparatus ED according to some implementations, FIG. 2 is an enlarged view illustrating a portion X of the substrate processing apparatus ED according to some implementations, and FIG. 3 is an enlarged view illustrating a portion X of the substrate processing apparatus ED according to some implementations.

Referring to FIG. 1, the substrate processing apparatus ED may be provided. The substrate processing apparatus ED may perform an etching process and/or a deposition process on a substrate W. For example, the substrate processing apparatus ED may perform a plasma-enhanced chemical vapor deposition (PECVD) process on the substrate W. However, implementations are not limited thereto, and in certain implementations, the substrate processing apparatus ED may perform an etching process on the substrate W. In the present specification, the term ‘the substrate W’ may mean, for example, a silicon (Si) wafer, but implementations are not limited thereto. The substrate processing apparatus ED may process the substrate W by using plasma. To achieve this, the substrate processing apparatus ED may generate the plasma by at least one of various methods. For example, the substrate processing apparatus ED may be a capacitively coupled plasma (CCP) apparatus and/or an inductively coupled plasma (ICP) apparatus. Hereinafter, the CCP apparatus will be included in the described examples for the purpose of ease and convenience in explanation. The substrate processing apparatus ED may include a process chamber 1, a stage 7, a shower head 3, an outer ring 51, a heating liner ring 53, a first power source 9, a plasma induction electrode PE, a heater HT, a second power source PW1, a third power source PW2, a monitoring unit MN, a control unit CP, a vacuum pump VP, and a gas supply unit GS.

The process chamber 1 may provide a process space 1h. A process may be performed on the substrate W in the process space 1h. The process space 1h may be separated from an external space. The process space 1h may be in a substantial vacuum state while the process is performed on the substrate W. The process chamber 1 may have, but is not limited to, a cylindrical shape.

Referring to FIG. 2, the stage 7 may be located in the process chamber 1. For example, the stage 7 may be located in the process space 1h. The stage 7 may support and/or fix the substrate W. The process may be performed on the substrate W in a state in which the substrate W is placed on the stage 7. The stage 7 may include aluminum nitride (AlN). However, implementations are not limited thereto. The stage 7 may further include a material having heat resistance, corrosion resistance, and high thermal conductivity. The stage 7 may include a stage body 71 and a cooling plate 73.

Referring to FIG. 2, the plasma induction electrode PE and the heater HT may be located in the stage body 71. The stage body 71 may include aluminum nitride. An edge ring ER may surround the stage body 71 when viewed in a plan view.

The cooling plate 73 may be located under the stage body 71. For example, the stage body 71 may be located on the cooling plate 73. The cooling plate 73 may provide a cooling hole (not shown). Cooling water may flow through the cooling hole. The cooling water in the cooling hole may absorb heat from the cooling plate 73.

The shower head 3 may be located in the process chamber 1. For example, the shower head 3 may be located in the process space 1h. The shower head 3 may be spaced upward from and apart from the stage 7. A gas supplied from the gas supply unit GS may be uniformly supplied into the process space 1h through the shower head 3.

The outer ring 51 may surround the shower head 3. For example, the outer ring 51 may be disposed outside the shower head 3 and may surround an edge of the shower head 3 when viewed in a plan view along the first direction D1. The outer ring 51 may be in contact with the shower head 3.

The heating liner ring 53 may surround the outer ring 51. For example, the heating liner ring 53 may be disposed outside the outer ring 51 and may surround an edge of the outer ring 51 when viewed in a plan view along the first direction D1. The heating liner ring 53 may support the outer ring 51. The heating liner ring 53 may include aluminum (Al) and yttrium oxide (Y₂O₃). More particularly, the heating liner ring 53 may have a shape in which aluminum (Al) is coated with yttrium oxide (Y₂O₃).

The plasma induction electrode PE may be used to generate plasma. More particularly, the plasma induction electrode PE may be supplied with RF power from the first power source 9 to generate the plasma. The plasma induction electrode PE may be located in the inside of the stage 7. The plasma induction electrode PE may have a plate shape. However, implementations are not limited thereto.

The heater HT may be located in the inside of the stage 7. The heater HT may be located under the plasma induction electrode PE. The heater HT may have a plate shape. However, implementations are not limited thereto. The heater HT may be supplied with AC power from the second power source PW1 to emit heat. The second power source PW1 may include an AC power source (not shown) for generating the AC power. A temperature of the stage 7 may be raised by the AC power. The temperature of the stage 7 may be raised to about 400° C. or more by the AC power supplied to the heater HT.

Referring to FIG. 2, the process space 1h in which the plasma is generated may be referred to as an A-layer A. A space including both a space between the stage 7 and the substrate W (if any), and the substrate W itself, may be referred to as a B-layer B. Referring to FIG. 3, the substrate W may be referred to as a Ba-layer Ba, and the space between the stage 7 and the substrate W may be referred to as a Bb-layer Bb. The B-layer B may include the Ba-layer Ba and the Bb-layer Bb. The Bb-layer Bb may mean an entire space between the substrate W and the stage 7. A shape of the Bb-layer Bb may be changed depending on a shape of the substrate W. More particularly, the shape of the Bb-layer Bb may be changed depending on fixation of the substrate W disposed on the stage 7. The Bb-layer Bb may be provided in plurality, depending on the shape of the substrate W. As a flatness of the substrate W becomes lower, a size and a number of the Bb-layer Bb may increase. As the flatness of the substrate W becomes higher, the size and the number of the Bb-layer Bb may decrease. The stage body 71 between a top surface of the stage 7 and a top surface of the plasma induction electrode PE may be referred to as a C-layer C or 71a. The plasma induction electrode PE may be referred to as a D-layer D. The stage body 71 between a bottom surface of the plasma induction electrode PE and a top surface of the heater HT may be referred to as an E-layer E or 71b. The heater HT may be referred to as a F-layer F. The AC power may be supplied to the F-layer F by the second power source PW1.

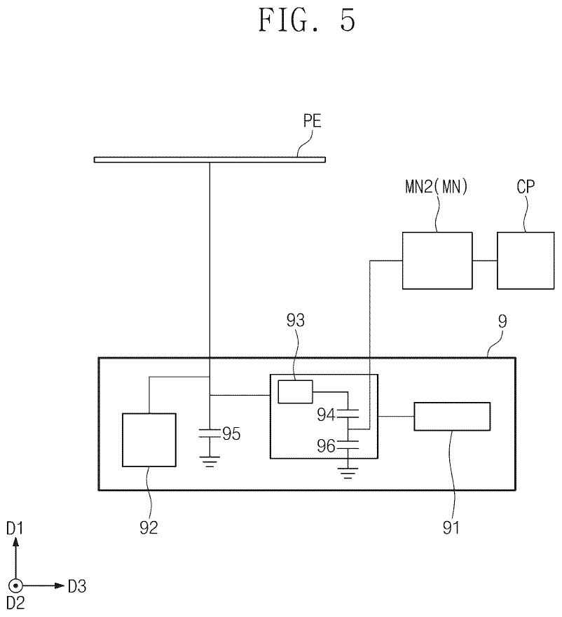

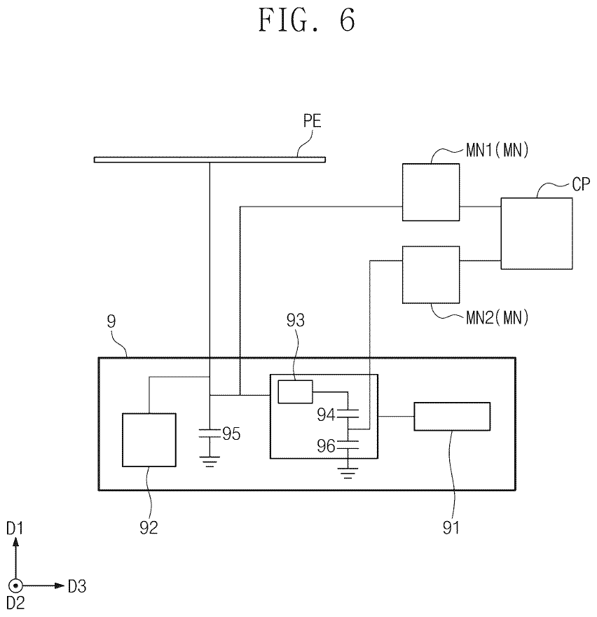

The first power source 9 may be configured to apply RF power and DC power to the stage 7. The first power source 9 (e.g., as shown in FIGS. 5-6) may include an RF power source 92, a DC power source 91, blocking capacitors 94, 95 and 96, and an alternating current filter 93 (see FIG. 5). The first power source 9 will be described below in detail, e.g., with respect to FIGS. 5-6.

The second power source PW1 may be configured to supply AC power to the stage 7. More particularly, the second power source PW1 may be configured to supply the AC power to the heater HT in the stage 7. An amplitude of the AC power supplied by the second power source PW1 may be constant. However, implementations are not limited thereto.

The third power source PW2 may be electrically connected to the shower head 3. The third power source PW2 may be located above the process space 1h. The third power source PW2 may be configured to supply RF power capable of generating the plasma. More particularly, the third power source PW2 may convert the gas supplied from the shower head 3 into the plasma. The third power source PW2 may more effectively generate the plasma in conjunction with the second power source PW1.

The vacuum pump VP may be connected to the process space 1h. A vacuum pressure may be applied to the process space 1h by the vacuum pump VP while the process is performed on the substrate W.

The monitoring unit MN may be electrically connected to the first power source 9. The monitoring unit MN may be electrically connected to the plasma induction electrode PE. The monitoring unit MN may include a first monitoring unit MN1 and a second monitoring unit MN2 (see FIG. 6). The monitoring unit MN may be configured to analyze the powers supplied from the first power source 9 and the second power source PW1.

The control unit CP may be electrically connected to the monitoring unit MN. The control unit CP may check a state of the substrate W by using information or data transmitted from the monitoring unit MN. More particularly, the control unit CP may check the fixed state and arcing of the substrate W together with the monitoring unit MN. This will be described below in detail.

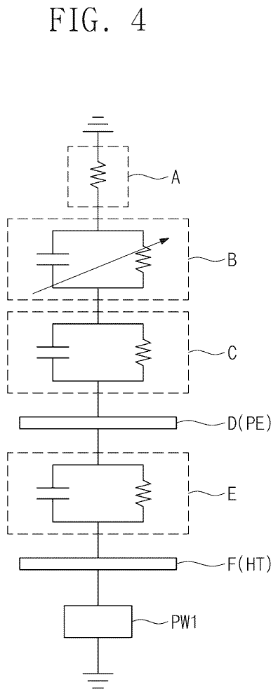

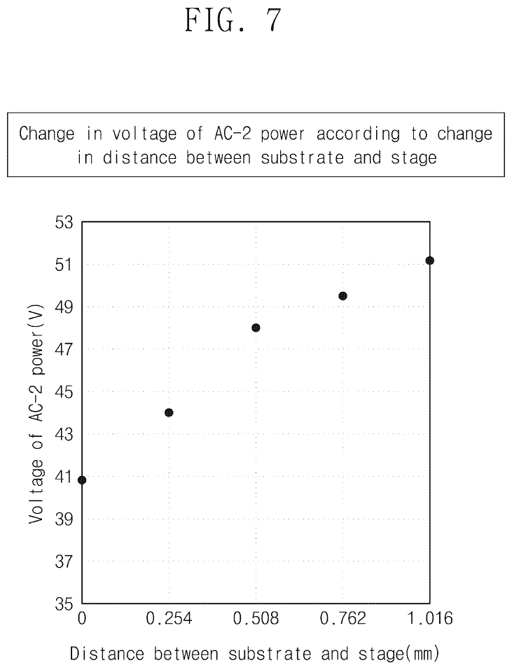

FIG. 4 is a schematic closed-circuit diagram illustrating a portion of the substrate processing apparatus ED according to some implementations, FIG. 5 is a schematic view illustrating the first power source 9 and the monitoring unit MN according to some implementations, FIG. 6 is a schematic view illustrating the first power source 9 and the monitoring unit MN according to some implementations, and FIG. 7 is a graph showing a change in heater voltage at the plasma induction electrode PE according to a change in distance between the substrate W and the stage 7.

Referring to FIG. 4, a portion of the substrate processing apparatus ED may be shown as a closed circuit. More particularly, a resistance of the A-layer A may be referred to as an A-resistance. A resistance of the B-layer B may be referred to as a first resistance. A resistance of the C-layer C may be referred to as a second resistance. A resistance of the E-layer E may be referred to as a third resistance. The AC power may be supplied to the F-layer F. The A-resistance, the second resistance and the third resistance may not be changed depending on the fixed state of the substrate W. The first resistance may be changed depending on the fixed state of the substrate W. More particularly, the first resistance may increase or decrease depending on the size, the shape and/or the number of the Bb-layer Bb.

Referring to FIG. 5, the plasma induction electrode PE may be electrically connected to the first power source 9. The plasma induction electrode PE may be configured to be supplied with the RF power and the DC power by the first power source 9. The first power source 9 may include the RF power source 92, the DC power source 91, the blocking capacitors 94, 95 and 96, and the alternating current filter 93. The RF power source 92 may be configured to generate the RF power. The DC power source 91 may be configured to generate the DC power. The plasma may be generated by the RF power. The substrate W may be fixed on the stage 7 by the DC power. The alternating current filter 93 may be located between the DC power source 91 and the plasma induction electrode PE. The alternating current filter 93 may be configured to filter the RF power supplied from the RF power source 92. The alternating current filter 93 may prevent a component of the RF power from being supplied to the DC power source 91.

The AC power may include AC-2 power supplied from an AC power source and transferred to the monitoring unit MN through the heater HT, the E-layer E and the plasma induction electrode PE. The AC-2 power may be power obtained by filtering the RF power, supplied from the RF power source 92, by the alternating current filter 93. For example, the AC-2 power may be power supplied from the second power source PW1 and transferred to the monitoring unit MN through the heater HT, the E-layer E, the plasma induction electrode PE and the alternating current filter 93. An amplitude of a voltage of the AC power may be constant. An amplitude of a voltage of the AC-2 power may be changed depending on the fixed state of the substrate W. The temperature of the stage 7 may be changed to change the third resistance, and thus the voltage of the AC-2 power may be changed. In addition, the first resistance may be changed, and thus the voltage of the AC-2 power may also be changed (see FIG. 7). The monitoring unit MN may be configured to measure the change in voltage of the AC-2 power.

Referring to FIG. 6, the monitoring unit MN may include the first monitoring unit MN1 and the second monitoring unit MN2. More particularly, the first monitoring unit MN1 may be configured to check an arcing state of the substrate W. The term ‘arcing’ means that when a high current flows at a low voltage to generate a spark, a surface of the substrate W is damaged by the spark. The second monitoring unit MN2 may be configured to check the fixed state of the substrate W. The first monitoring unit MN1 may be configured to measure RF-2 power of the RF power, which is transferred before reaching the alternating current filter 93. For example, the RF-2 power may be power supplied from the RF power source 92 through the heater HT and the plasma induction electrode PE and transferred to the monitoring unit MN before passing through the alternating current filter 93. The first monitoring unit MN1 may be configured to measure a change in the RF-2 power supplied from the RF power source 92 through the heater HT and the plasma induction electrode PE and transferred before passing through the alternating current filter 93. The second monitoring unit MN2 may be configured to measure a change in the AC-2 power supplied from the second power source PW1 and transferred through the heater HT, the plasma induction electrode PE and the alternating current filter 93.

The blocking capacitors 94, 95 and 96 may include a first blocking capacitor 95, a second blocking capacitor 94, and a third blocking capacitor 96. The first blocking capacitor 95 and the DC power source 91 may be connected in parallel to the plasma induction electrode PE. The first blocking capacitor 95 may prevent the first power source 9 from making a short circuit. The second blocking capacitor 94 and the third blocking capacitor 96 may be connected in series to the alternating current filter 93. However, implementations are not limited thereto. The first monitoring unit MN1 may be connected to the first power source 9 between the RF power source 92 and the alternating current filter 93. The second monitoring unit MN2 may be electrically connected to a place at which power passed through the plasma induction electrode PE passes through the alternating current filter 93 and the second blocking capacitor 94.

Referring to FIG. 7, an example of changes in voltage of the AC-2 power according to a change in distance between the substrate W and the stage 7 is provided. A horizontal axis of the graph shows the distance between the substrate W and the stage 7. A vertical axis of the graph shows the voltage of the AC-2 power. The substrate W may be in contact with the stage 7 at first. Initially the distance between the substrate W and the stage 7 may be zero (0). The distance between the substrate W and the stage 7 may increase. The Bb-layer Bb may increase. The voltage of the AC-2 power may be changed as the distance between the substrate W and the stage 7 increases. For example, the voltage of the AC-2 power may be changed as the first resistance is changed. As the distance between the substrate W and the stage 7 increases, the voltage of the AC-2 power may increase. Under the same other experimental conditions (e.g., the temperature of the stage 7, etc.), the voltage of the AC-2 power may be changed depending on the distance between the substrate W and the stage 7. When the distance between the substrate W and the stage 7 is constant, the voltage of the AC-2 power may be constant, also.

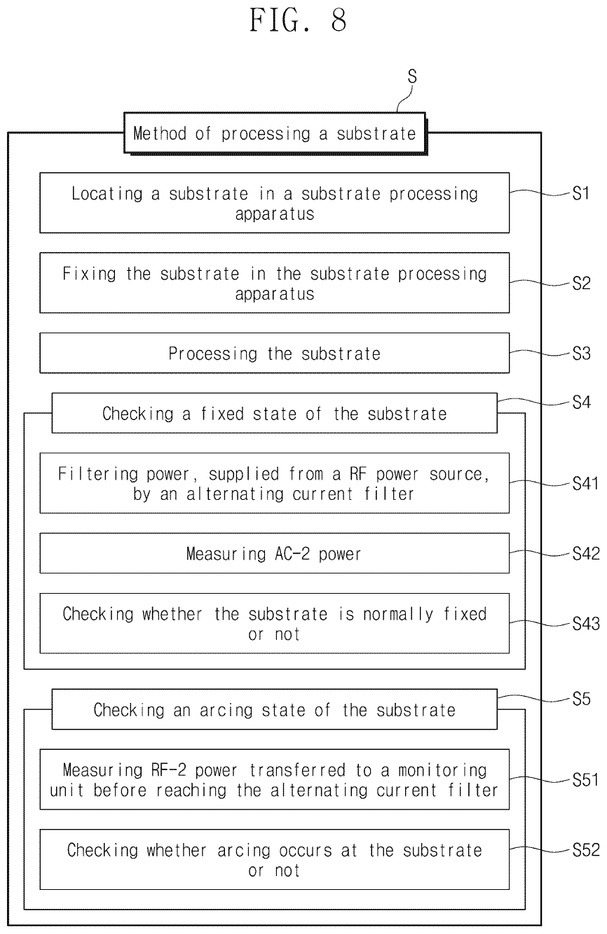

FIG. 8 is a flow chart illustrating a method of processing a substrate(S) according to some implementations.

Referring to FIG. 8, the method of processing a substrate(S) may include locating/providing a substrate W in a substrate processing apparatus ED (S1); fixing the substrate W in the substrate processing apparatus ED (S2), processing the substrate W (S3); checking a fixed state of the substrate W (S4); and checking an arcing state of the substrate W (S5). The checking of the fixed state of the substrate W (S4) may include filtering power (e.g., power supplied from an RF power source 92), such as by an alternating current filter 93 (S41); measuring AC-2 power (S42); and checking whether the substrate W is normally fixed or not (S43) based on the AC-2 power. The checking of the arcing state of the substrate W (S5) may include measuring RF-2 power transferred to a monitoring unit MN before reaching the alternating current filter 93 (S51), and checking whether arcing occurs at the substrate W or not (S52) based on the RF-2 power transferred to the monitoring unit MN before reaching the alternating current filter 93.

The processing of the substrate W (S4) may include heating the stage 7 by supplying the AC power to the heater HT by the second power source PW1. For example, the processing of the substrate W (S4) may include heating the stage 7 by supplying the AC power to the heater HT by the AC power source. The processing of the substrate W (S4) may further include supplying the RF power to the plasma induction electrode PE by the RF power source 92.

The filtering of the power, supplied from the RF power source 92, by the alternating current filter 93 (S41) and the measuring of the AC-2 power (S42) may include measuring the AC-2 power transferred from the AC power source to the monitoring unit MN through the heater HT, the plasma induction electrode PE and the alternating current filter 93.

The measuring of the RF-2 power transferred to the monitoring unit MN before reaching the alternating current filter 93 (S51) may include measuring the RF-2 power supplied from the RF power source 92 and transferred to the monitoring unit MN through the substrate W and the plasma induction electrode PE before reaching the alternating current filter 93.

The checking of whether the arcing occurs at the substrate W or not (S52) may include analyzing the RF-2 power.

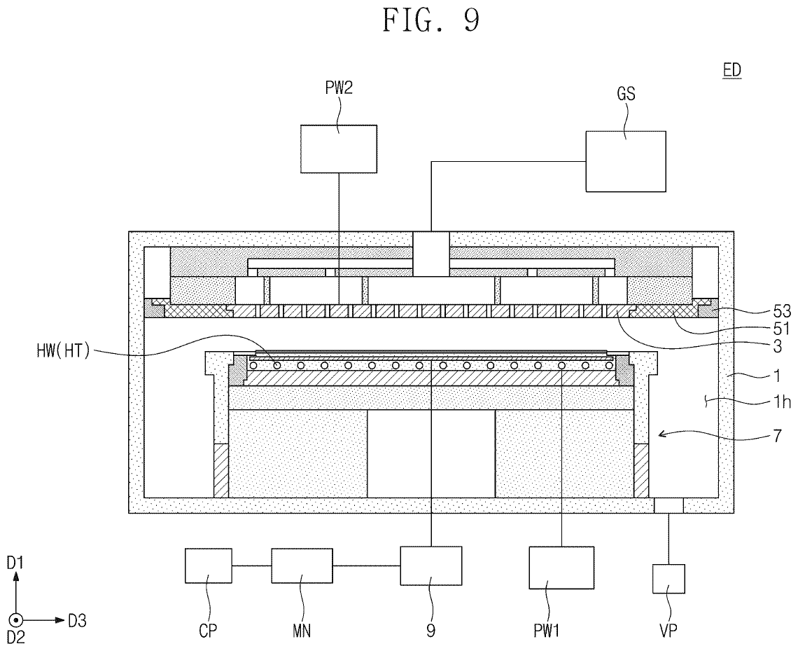

FIG. 9 is a cross-sectional view illustrating a substrate processing apparatus ED according to some implementations.

Referring to FIG. 9, a substrate processing apparatus ED may include a heater HT having a shape different from that of FIG. 1. The heater HT may have a shape different from the plate shape. For example, the heater HT may include concentric heating wires HW.

According some implementations of processing a substrate, the fixed state of the substrate may be checked regardless of DC power formed by plasma, which can be beneficial. For example, if a state of a substrate is checked using a leakage current of DC power at a stage, accuracy may be deteriorated by the DC power formed by the plasma. By contrast, a frequency of the voltage of the AC-2 power filtered at the plasma induction electrode by the alternating current filter may be different from a frequency of the DC power formed by the plasma, and thus the AC-2 power may not be affected by the DC power formed by the plasma. The change in the AC power applied to the heater and passing through the substrate and the plasma induction electrode may be analyzed to check the fixed state of the substrate regardless of the DC power formed by the plasma.

According to some implementations of processing a substrate, the fixed state of the substrate may be checked regardless of a type of the stage. The stage may include a mono-polar stage including a single plasma induction electrode or a bi-polar stage including two plasma induction electrodes. The mono-polar stage may be incompatible with a method of checking a fixed state of a substrate by using a change in capacitance between the stage and the substrate. However, the fixed state of the substrate on the mono-polar stage may be checked using the AC power applied to the heater.

According to some implementations of processing a substrate, the fixed state of the substrate may be checked and the arcing state of the substrate may also be checked. The RF-2 power supplied from the RF power source and passed through the substrate and the plasma induction electrode may be monitored and analyzed to check the arcing state of the substrate.

Advantages provided by some implementations according to this disclosure include at least the following. In implementations, the fixed state of the substrate may be checked by measuring the heater voltage at the plasma induction electrode. In some implementations, the fixed state of the substrate may be checked regardless of the type of the plasma induction electrode. In some implementations, the fixed state of the substrate may be checked without measuring a change in gas leakage. In some implementations, the fixed state of the substrate may be checked at a high process temperature. In some implementations, it is possible to measure a change in heater voltage at the plasma induction electrode according to a change in resistance according to a change in contact state between the substrate and the stage.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While some implementations have been particularly shown and described, it will be understood by one of ordinary skill in the art that variations in form and detail may be made therein without departing from the spirit and scope of the attached claims.

What is claimed is:

1. A method of processing a substrate, the method comprising:
fixing a substrate in a substrate processing apparatus, wherein the substrate processing apparatus comprises:
a process chamber providing a process space,
a stage supporting the substrate,
a plasma induction electrode configured to generate plasma and located in the stage,
a first power source configured to supply radio frequency (RF) power to the plasma induction electrode;
a heater located in the stage and configured to heat the stage,
a second power source configured to supply alternating current (AC) power to the heater, and
a monitoring unit electrically connected to the plasma induction electrode;
processing the substrate, wherein processing the substrate comprises heating the stage by supplying the AC power to the heater using the second power source; and
checking a state of fixation of the substrate, wherein checking the state of fixation of the substrate comprises measuring a component of the AC power that is transferred to the monitoring unit through the heater and the plasma induction electrode.

2. The method of claim 1, wherein the first power source comprises:
a direct current (DC) power source configured to fix the substrate on the stage;
an RF power source configured to generate plasma; and
an alternating current filter configured to filter RF power supplied from the RF power source,
wherein the alternating current filter is located between the DC power source and the plasma induction electrode, and
wherein the monitoring unit is connected to the first power source between the DC power source and the alternating current filter.

3. The method of claim 2, wherein checking the state of fixation of the substrate comprises:
filtering the RF power supplied from the RF power source using the alternating current filter, before measuring the component of the AC power.

4. The method of claim 2, wherein processing the substrate comprises supplying the RF power to the plasma induction electrode using the RF power source, and wherein the method further comprises:
checking an arcing state of the substrate after fixing the substrate on the stage,
wherein checking of the arcing state of the substrate comprises measuring a component of the RF power that is transferred to the monitoring unit, before the component of the RF power reaches the alternating current filter.

5. The method of claim 1, wherein measuring the component of the AC power comprises: measuring a change in voltage of the component of the AC power, the change in voltage responsive to a change in resistance between the substrate and the stage.

6. The method of claim 1, wherein the substrate processing apparatus further comprises:
a shower head spaced vertically above the stage in the process space; and
a third power source electrically connected to the shower head and configured to induce generation of plasma.

7. The method of claim 1, wherein the stage includes aluminum nitride (AlN).

8. The method of claim 1, wherein processing the substrate further comprises raising a temperature of the stage to 400° C. or more using the AC power supplied to the heater.

9. The method of claim 1, wherein an amplitude of the AC power supplied by the second power source is constant.

10. A method of processing a substrate, the method comprising:
fixing a substrate in a substrate processing apparatus, wherein the substrate processing apparatus comprises
a process chamber providing a process space,
a stage supporting the substrate,
a plasma induction electrode configured to generate plasma,
a first power source comprising a radio frequency (RF) power source configured to supply RF power to the plasma induction electrode, and an alternating current filter configured to filter the RF power,
a heater located in the stage and configured to heat the stage;
a second power source configured to supply alternating current (AC) power to the heater, and
a monitoring unit configured to measure a change in a component of the AC power that is supplied from the second power source and passed through the heater, the plasma induction electrode and the alternating current filter;
processing the substrate using the substrate processing apparatus; and
checking a state of fixation of the substrate, wherein checking the state of fixation of the substrate comprises measuring the component of the AC power.

11. The method of claim 10, wherein the second power source is configured to generate the AC power with a constant amplitude, and
wherein an amplitude of a voltage of the component of the AC power changes based on the state of fixation of the substrate.

12. The method of claim 10, wherein the stage includes aluminum nitride (AlN).

13. The method of claim 10, wherein the first power source further comprises:
a direct current (DC) power source configured to fix the substrate on the stage; and
a blocking capacitor connected to the plasma induction electrode, wherein the blocking capacitor and the DC power source are connected in parallel with the plasma induction electrode.

14. The method of claim 10, wherein measuring the component of the AC power comprises measuring a change in voltage of the component of the AC power, the change in voltage responsive to a change in resistance between the substrate and the stage.

15. The method of claim 10, wherein the substrate processing apparatus further comprises:
a shower head configured to inject a gas into the process space; and
a third power source connected to the shower head and configured to convert the gas into plasma.

16. The method of claim 10, further comprising:
measuring a component of the RF power that is transferred to the monitoring unit through the plasma induction electrode, before the component of the RF power reaches the alternating current filter; and
determining whether arcing occurs at the substrate based on the component of the RF power.

17. A method of processing a substrate, the method comprising:
fixing a substrate in a substrate processing apparatus, wherein the substrate processing apparatus comprises:
a process chamber providing a process space,
a stage supporting the substrate,
a plasma induction electrode located in the stage and configured to generate plasma,
a first power source comprising a radio frequency (RF) power source electrically connected to the plasma induction electrode and configured to supply RF power,
a heater located in the stage and configured to heat the stage,
a second power source comprising an alternating current (AC) power source configured to supply AC power to the heater, and
a monitoring unit connected to the first power source and configured to analyze a state of the substrate;
processing the substrate, wherein processing the substrate comprises heating the stage by supplying the AC power to the heater;
checking a state of fixation of the substrate by measuring a component of the AC power that is transferred from the AC power source to the monitoring unit through the heater and the plasma induction electrode; and
checking an arcing state of the substrate by measuring a component of the RF power that is transferred to the monitoring unit through the substrate and the plasma induction electrode.

18. The method of claim 17, wherein the first power source comprises an alternating current filter configured to filter the RF power, and
wherein measuring the component of the AC power comprises measuring a voltage of the component of the AC power, wherein the component of the AC power is passed through the alternating current filter.

19. The method of claim 18, wherein measuring the component of the RF power comprises measuring a voltage of the component of the RF power, wherein the component of the RF power is not passed through the alternating current filter.

20. The method of claim 17, wherein the substrate processing apparatus further comprises a third power source configured to generate plasma and located above the process space.
